(19) United States
(12) Patent Application Publication
(10) Pub. No.: US 2026/0105978 A1
(43) Pub. Date: Apr. 16, 2026

(54) DRAM-BASED ONE TIME PROGRAMMING MEMORY

(71) Applicant: AP MEMORY TECHNOLOGY CORPORATION, HSINCHU COUNTY (TW)

(72) Inventor: WENLIANG CHEN, HSINCHU COUNTY (TW)

(21) Appl. No.: 19/204,454

(22) Filed: May 9, 2025

Related U.S. Application Data
(60) Provisional application No. 63/706,046, filed on Oct. 11, 2024.

(51) Int. Cl. G11C 17/16; G11C 17/18; H01L 23/00; H01L 25/065; H01L 25/18; H10B 20/25; H10B 80/00

(52) U.S. Cl. CPC G11C 17/16; G11C 17/18; H10B 20/25; H10B 80/00; H10W 90/00; H10W 90/297; H10W 90/722; H10W 90/792

(57) ABSTRACT

A dynamic random-access memory (DRAM)-based one time programming (OTP) memory device includes: at least one memory bank comprising a plurality of memory array tiles (MATs) arranged in a matrix. Each of the plurality of MATs includes: a plurality of word lines extending along a row direction; a plurality of bit lines extending along a column direction; and a plurality of memory cells located on corresponding cross points of the plurality of word lines and the plurality of bit lines, each of the plurality of memory cells comprising a capacitor node. The capacitor nodes of the plurality of memory cells along the column direction in the memory bank are divided into a plurality of capacitor node segments, wherein at least two of the plurality of capacitor node segments are separately controllable.

### PRIORITY CLAIM AND CROSS-REFERENCE

This application claims priority to U.S. Provisional Application No. 63/706,046 filed Oct. 11, 2024, the disclosure of which is hereby incorporated by reference in its their entirety.

### BACKGROUND

Computer systems generally contain non-volatile memory used for storing instruction codes and data, and volatile memory used as working memory. DRAM (dynamic random-access memory) is the primary form of the working memory. In a conventional computer system, the volatile memory and the non-volatile memory are formed and configured separately, and their use scenarios are not inter-changeable. As more and more new applications emerge, e.g., AI inference, machine learning, or the like, the data of such applications need to be stored in DRAM for quick access with low power consumption. Further, these data also need to be stored permanently in the computer system. Therefore, there is an increasing need to improve the DRAM configuration to address the demands of the quick and low-power access requirements while maintaining data permanently.

### SUMMARY

According to one aspect of the present disclosure, a dynamic random-access memory (DRAM)-based one time programming (OTP) memory device includes: at least one memory bank comprising a plurality of memory array tiles (MATs) arranged in a matrix, wherein each of the plurality of MATs includes: a plurality of word lines extending along a row direction; a plurality of bit lines extending along a column direction; and a plurality of memory cells located on corresponding cross points of the plurality of word lines and the plurality of bit lines, each of the plurality of memory cells comprising a capacitor node. The capacitor nodes of the plurality of memory cells along the column direction in the memory bank are divided into a plurality of capacitor node segments, wherein at least two of the plurality of capacitor node segments are separately controllable.

According to another aspect of the present disclosure, a semiconductor package includes: a substrate; a DRAM memory device formed in the substrate; and a DRAM-based OTP memory device formed in the substrate. The DRAM-based OTP memory device includes: at least one memory bank having a plurality of memory array tiles (MATs) arranged in a matrix, wherein each of the plurality of MATs includes: a plurality of word lines extending along a row direction; a plurality of bit lines extending along a column direction; and a plurality of memory cells located on corresponding cross points of the plurality of word lines and the plurality of bit lines, each of the plurality of memory cells comprising a capacitor node. The capacitor nodes of the plurality of memory cells along the column direction in the memory bank are divided into a plurality of capacitor node segments. At least two of the plurality of capacitor node segments are separately controllable.

According to yet another aspect of the present disclosure, a semiconductor package includes: a logic device formed in a first substrate; a DRAM-based OTP memory device formed in a second substrate and stacking on the logic device. The DRAM-based OTP memory device includes: at least one memory bank having a plurality of memory array tiles (MATs) arranged in a matrix, wherein each of the plurality of MATs includes: a plurality of word lines extending along a row direction; a plurality of bit lines extending along a column direction; and a plurality of memory cells located on corresponding cross points of the plurality of word lines and the plurality of bit lines, each of the plurality of memory cells comprising a capacitor node. The capacitor nodes of the plurality of memory cells along the column direction in the memory bank are divided into a plurality of capacitor node segments. At least two of the plurality of capacitor node segments are separately controllable.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A and 1B are schematic diagrams of a memory device, in accordance with various embodiments of the present disclosure.

FIG. 2 is a schematic diagram of an OTP programming operation on a memory cell, in accordance with some embodiments of the present disclosure.

FIGS. 3A, 3B, 3C and 3D are schematic diagrams of an OTP memory device, in accordance with various embodiments of the present disclosure.

FIG. 4 is a schematic diagram of a comparator of a memory device, in accordance with various embodiments of the present disclosure.

FIGS. 5A, 5B, 5C, 5D, 5E, 5F and 5G are schematic diagrams of an OTP memory device, in accordance with various embodiments of the present disclosure.

FIGS. 6A, 6B and 6C are schematic diagrams of a memory device, in accordance with various embodiments of the present disclosure.

FIGS. 7A, 7B, 7C, 7D, 7E, 7F, 7G and 7H are schematic diagrams of a semiconductor package, in accordance with various embodiments of the present disclosure.

### DETAILED DESCRIPTION

The following disclosure provides many different embodiments, or examples, for implementing different features of the provided subject matter. Specific examples of components and arrangements are described in the present disclosure in order to facilitate understanding of the invention. Such examples are merely provided to aid in understanding and are not intended to limit the present disclosure. For example, the formation of a first feature over or on a second feature as described herein may include embodiments in which the first and second features are formed in direct contact, and may also include embodiments in which additional features are formed between the first and second features, such that the first and second features are not in direct contact. In addition, the present disclosure may repeat reference numerals and/or letters in the various examples. Such repetition is for the purpose of simplicity and clarity and does not necessarily indicate a relationship between the various embodiments and/or configurations described.

Further, spatially relative terms, such as “beneath,” “below,” “lower,” “above,” “upper” and the like, may be used herein for ease of description to describe one element or feature's relationship to another element(s) or feature(s) as illustrated in the figures. Such spatially relative terms are intended to encompass different orientations of the device in use or operation in addition to the orientation depicted in the figures. The apparatus may be otherwise oriented (for example, rotated 90 degrees from the depicted orientation) and the spatially relative descriptors used herein should accordingly be interpreted as including other orientations.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the deviation normally found in the respective testing measurements. Also, as used herein, the terms “about,” “approximately” or “substantially” may mean within some small percentage of a given value or range. Alternatively, the terms “about,” “approximately” or “substantially” mean within an acceptable standard error of the value indicated when considered by one of ordinary skill in the art. Unless expressly specified otherwise, all of the numerical ranges, amounts, values and percentages such as those for quantities of materials, durations of time, temperatures, operating conditions, ratios of amounts, and the likes thereof disclosed herein should be understood as modified in all instances by the terms “about,” “approximately” or “substantially.” Accordingly, unless indicated otherwise, the numerical parameters set forth in the present disclosure and attached claims are approximations that can vary. At the very least, each numerical parameter should be construed in light of the number of reported significant digits and by applying ordinary rounding techniques. Ranges are expressed herein as from one endpoint to another endpoint, or as between one endpoint and another endpoint. All ranges disclosed herein are inclusive of the endpoints, unless specified otherwise.

The present disclosure relates generally to a DRAM (dynamic random-access memory) device and an operating method thereof, and particularly to one-time-programming (OTP) memory cells formed from DRAM-based memory cells and an operating method thereof.

DRAM is a type of memory widely adopted throughout the industrial, semiconductor, electronic and consumer markets. The DRAM provides advantages such as fast access speed, simple device structure and low power consumption. Generally, the DRAM belongs to a volatile-type memory in contrast to the non-volatile-type memory, e.g., ROM (read-only memory), and is most often used in devices where instruction codes or data are accessed from or to the DRAM memory cells when these devices are powered-on. However, as new applications emerge, such as artificial intelligence (AI) training models, the amount of processing data, whose contents do not change frequently but need to be rapidly accessed from the DRAM memory cells, has increased in an amazing speed. As such, there is a need to provide a memory device that can support both of the volatile-type and non-volatile-type memory cells in a dynamic manner. To address the abovementioned issues, the present disclosure proposes DRAM-based one-time-programming (OTP) memory cells and an operating (including programming and reading) method for the OTP memory cells. With the proposed OTP memory cells in the existing DRAM device, data can be stored permanently in the OTP memory cells, and therefore non-volatile data can co-exist with the volatile data in the DRAM memory device. For example, data of the training models can be stored permanently in the OTP memory cells while the instruction or other variable data can be stored and overwritten in the conventional DRAM memory cells on demand. Thus, the system performance of the DRAM memory device can be enhanced, and the operation power of the DRAM system can be further reduced.

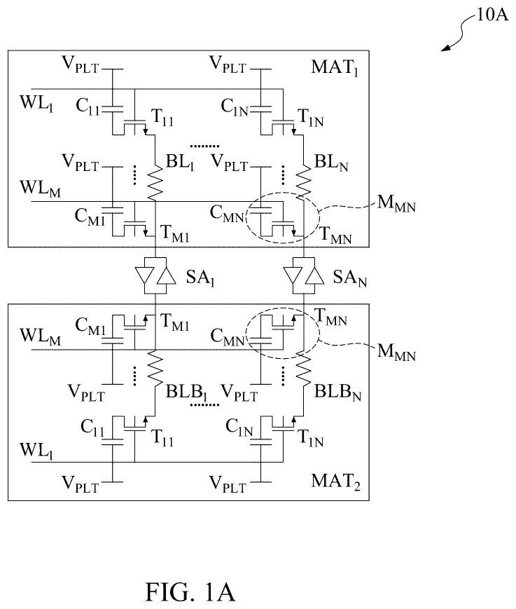

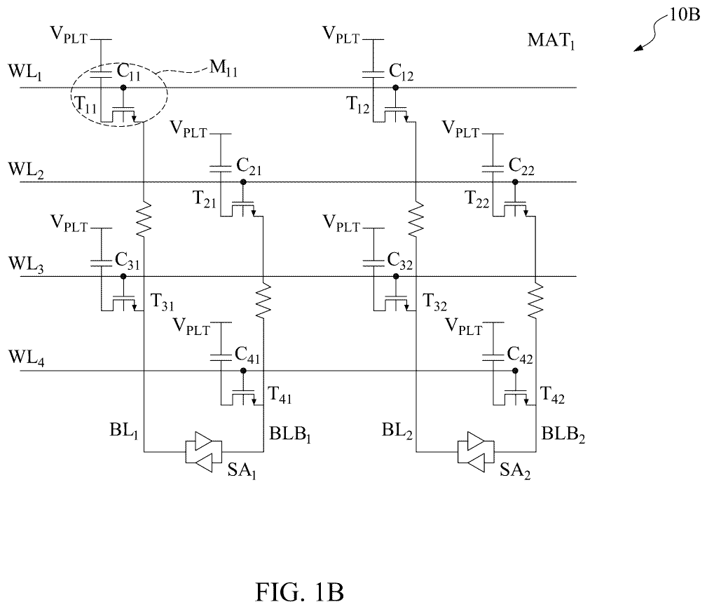

FIG. 1A is a schematic diagram of a memory device 10A, in accordance with various embodiments of the present disclosure. According to some embodiments, the memory device 10A is a DRAM device formed of a plurality of DRAM memory cells. The memory device 10A may include a substrate (not separately shown) on which the DRAM memory cells are formed. The memory device 10A may include multiple arrays of memory cells, e.g., at least one memory bank, in the unit of memory array tile (MAT). FIG. 1A only shows two MATs MAT₁ and MAT₂ for illustrative purposes, but the present disclosure is not limited thereto. The memory device 10A can includes only one or more than two MATs.

According to some embodiments, the MAT MAT₁ or MAT₂ includes a plurality of word lines (WL) WLₘ (m=1, 2, . . . , M) extending in parallel in a row (horizontal) direction, and a plurality of bit lines (BLₙ) or complementary bit lines (BLB_{n) (n=}1, 2, . . . , N) extending in a column (vertical) direction. The bit line BLₙ and the complementary bit line BLBₙ form a pair of complementary bit lines. The MAT MAT₁ or MAT₂ may further include an array of memory cells Mₘₙ arranged in rows and columns and located on the cross points of the word lines WLₘ and the bit lines BLₙ or complementary bit lines BLBₙ. Each memory cell Mₘₙ comprises a capacitor Cₘₙ and an access transistor Tₘₙ coupled to the capacitor Cₘₙ, wherein the capacitor Cₘₙ is also referred to the storage node Cₘₙ of the memory cells Mₘₙ. According to some embodiments, the quantity of charges stored in the capacitor Cₘₙ represents the logic states of the corresponding memory cell Mₘₙ. For example, the capacitor Cₘₙ represents a logic high state (logic “1”) when it is charged, and represents a logic low state (logic “0”) when it is discharged.

According to some embodiments, the memory device 10A further includes a row of sense amplifiers SA₁, SA₂, . . . SA_{N} configured to read data from or write data to the memory cells Mₘ₁, Mₘ₂, . . . M_{mN} in the m-th row. For example, each of the row of sense amplifiers SA₁, SA₂, . . . SA_{N} are configured to receive two complementary input voltages from the corresponding pair of bit lines BLₙ and BLBₙ, perform signal amplification on the received input voltages and output a pair of amplified and complementary logic states as the read-out data of the accessed memory cells Mₘₙ. According to some embodiments, the row of sense amplifiers SA₁, SA₂, . . . SA_{N} is configured to receive writing voltages corresponding to predetermined write data, and charge or discharge the capacitors Cₘₙ of the corresponding memory cells Mₘₙ according to the writing voltages of the sense amplifiers SA₁, SA₂, . . . SA_{N}.

The access transistor Tₘₙ is configured to control the writing and reading operations of the capacitor Cₘₙ. The word line WLₘ is configured to control the turn-on of turn-off of the m-th row of the MAT MAT₁ or MAT₂ through transmitting a high-voltage signal or a low-voltage signal, respectively, to the gate of the access transistor Tₘₙ. During the reading operation, for example, the bit line BLₙ and the corresponding complementary bit line BLBₙ of the selected n-th column is configured to be set to a reference voltage, and the access transistor Tₘₙ is turned on through setting a high-voltage signal to a selected m-th row in the selected MAT MAT₁, and the bit line BLₙ of the selected n-th column is configured to receive the voltage variation resulting from the charge state of the capacitor Cₘₙ. At that time, the complementary bit line BLBₙ maintain the reference voltage due to the disablement of the access transistors in MAT MAT₂. Then, the sense amplifier SAₙ is configured to sense the voltage difference between the bit line BLₙ and the complementary bit line BLBₙ, and output the read-out logic states according to the sensed voltage difference. According to some embodiments, the sense amplifier SAₙ is formed of two cross-coupled inverters, and therefore the logic states (or voltages) on the bit line BLₙ and the complementary bit line BLBₙ are complementary to each other after receiving the voltage variation resulting from the capacitor Cₘₙ due to the inverted logic states of the outputs of the two inverters in the sense amplifiers SAₙ.

During the writing operation, for example, the access transistor Tₘₙ is turned on through setting a high-voltage signal to a selected m-th row in the select MAT MAT₁, and the selected bit line BLₙ are charged with a writing voltage corresponding to the logic states of the predetermined write data. The capacitor Cₘₙ of the corresponding memory cell Mₘₙ is then written with the writing voltage on the bit line BLₙ. Throughout the present disclosure, the memory cell functioning as volatile DRAM memory cells are referred to as a normal DRAM memory cell, and the reading operation and the writing operation of the normal memory cells of the DRAM device, e.g., the memory device 10A, is collectively referred to as a normal DRAM (access) operation.

According to some embodiments, the capacitor Cₘₙ is formed of two electrodes and an electrically insulating layer sandwiched between the two electrodes. Throughout the present disclosure, a plate electrically coupled to one of the two electrodes and configured to receive a cell plate voltage V_{PLT} is referred to a cell plate or a capacitor node of the capacitor Cₘₙ. The electrically insulating layer may be formed of a dielectric film, such as oxide, nitride,, oxynitride, oxides of Lanthanum, Hafnium, and Zirconium, or other suitable dielectric materials. During the reading or writing operation, one of the two electrodes is biased at a cell plate voltage V_{PLT}. During a normal operation, when the access transistor Tₘₙ of the corresponding capacitor Cₘₙ is turned on, the capacitor Cₘₙ will be charged or discharged based on the relative voltages on capacitor Cₘₙ and the corresponding bit line BLₘ or the complementary bit line BLBₘ. According to some embodiments, the cell plate voltage V_{PLT} is kept substantially equal for all of the memory cells Cₘₙ in the memory device 10A to ensure the memory cell Cₘₙ will function properly in a normal reading or writing operation. According to some embodiments, the capacitor Cₘₙ is charged to a logic high state represented by a high voltage, e.g., about one volt and discharged to a logic low state represented by a low voltage, e.g., about zero volts. According to some embodiments, in a normal operation, the cell plate voltage V_{PLT} is set as zero volts or one half of the voltage of the logic high state, and can be about 0.5 volts. According to some embodiments, in a normal operation, the maximum voltage difference between the two electrodes of the capacitors Cₘₙ is controlled within at around 0.5 volts no matter the capacitor Cₘₙ is in a logic high state or a logic low state to reduce the voltage stress caused by the voltage difference applied on the two electrodes. According to some embodiments, the cell plate voltage V_{PLT}, the high voltage and the low voltage for the corresponding logic high state and logic low state are determined such that the voltage difference on two sides of the electrically insulating layer of the capacitor Cₘₙ is lower than the breakdown voltage of the electrically insulating layer to ensure a proper operation of the capacitor Cₘₙ. According to some embodiments, the sense amplifier SAₙ is operated to provide an array voltage V_{ARY}, where the array voltage V_{ARY} is used as a supply voltage for the sense amplifiers SAₙ and set at about 1 to about 1.8 volts during a normal operation.

According to some embodiments, when the word line WLₘ is selected to turn on the corresponding row of access transistors Tₘₙ, the word line WLₘ is set at an access voltage Vₚₚ about 2.7 volts. According to some embodiments, when the word line WLₘ is disabled and turns off the corresponding row of access transistors Tₘₙ, the word line WLₘ is set at a voltage Vₖₖ in a range between about −0.3 volts and about 0 volts.

According to some embodiments, referring to FIG. 1A, the row of sense amplifiers SA₁, SA₂, . . . SA_{N} is arranged between and shared by the two adjacent MATs MAT₁ and MAT₂, and throughout the present disclosure the configuration of the memory device 10A is referred to as open bit line structure. During operation, only one word line WLₘ in one of the adjacent MATs (for example, MAT₁) is accessed, while all the memory cells on the other word lines of the access MAT (i.e., MAT₁) and all memory cells of the other MAT (for example, MAT₂) are disabled. Among the pair of complementary bit lines of the sense amplifier SAₙ, one bit line of the bit line BLₘ and the complementary bit line BLBₘ, which corresponds to the accessed memory cell Mₘₙ, is configured to sense the voltage of the capacitor Cₘₙ, while the other bit line of the bit line BLₘ and the complementary bit line BLBₘ of the disabled MAT (i.e., MAT₂) is charged with a reference voltage, e.g., one half of the array voltage V_{ARY}, for use of data sensing by the sense amplifier SAₙ.

FIG. 1B is a schematic diagram of a memory device 10B, in accordance with various embodiments of the present disclosure. According to some embodiments, the memory device 10B is a DRAM device formed of a plurality of DRAM memory cells. The memory device 10B may include multiple arrays of memory cells in the unit of memory array tile (MAT). FIG. 1B only shows one MAT MAT₁ for illustrative purposes, but the present disclosure is not limited thereto.

The memory device 10B is similar to the memory device 10A in many aspects, and descriptions of these similar features are not repeated for brevity. The major difference between the memory device 10B and the memory device 10A is the sense amplifiers, e.g., sense amplifiers SA₁, SA₂, are shared by and connected to at least two memory cells Mₘₙ in the same MAT. For example, the memory cells M₁₁ and M₃₁ are connected to the bit line BL₁, while the memory cells M₂₁ and M₄₁ are connected to the complementary bit line BLB₁, where the bit line BL₁ and complementary bit line BLB₁ are complementary bit lines of the sense amplifier SA₁. Similarly, the memory cells M₁₂ and M₃₂ are connected to the bit line BL₂, while the memory cells M₂₂ and M₄₂ are connected to the complementary bit line BLB₂, where the bit line BL₂ and complementary bit line BLB₂ are complementary bit lines of the sense amplifier SA₂. Throughout the present disclosure the configuration of the memory device 10B is referred to as folded bit line structure.

According to some embodiments, more than one memory cells Mₘₙ are electrically coupled to one bit line BL₁ or BL₂ or complementary bit line BLB₁ or BLB₂. During operation, only one word line WLₘ in the MAT (for example, MAT₁) is accessed, while all the memory cells on the other word lines of the access MAT (i.e., MAT₁) are disabled. Among the two complementary bit lines of the sense amplifier SAₙ, one of the bit line BLₘ and the complementary bit line BLBₘ, which corresponds to the accessed memory cell Mₘₙ, is configured to sense the voltage of the capacitor Cₘₙ, while the other bit line of the bit line BLₘ and the complementary bit line BLBₘ, which corresponds to a disabled memory cell Mₘₙ, is charged with a reference voltage, e.g., one half of the array voltage V_{ARY}, for use of data sensing by the sense amplifier SAₙ.

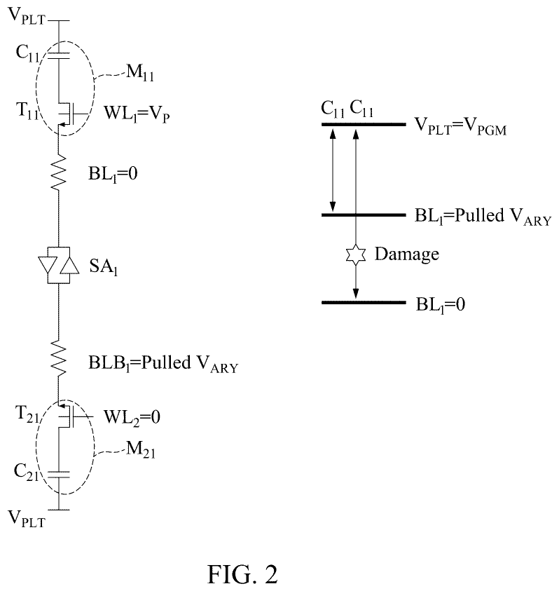

FIG. 2 is a schematic diagram of a programming operation on a memory cell M₁₁, in accordance with some embodiments of the present disclosure. FIG. 2 shows in a left subfigure a memory device 20 including a plurality of memory columns, although only an example memory column is illustrated. The memory column may be formed with an open bit line structure, as shown in FIG. 1A, or formed with a folded bit line structure, as shown in FIG. 1B. The memory column includes a first memory cell M₁₁ in a first row, a second memory cell M₂₁ in a second row, a bit line BL₁ connected to the first memory cell M₁₁, a complementary bit line BLB₁ connected to the second memory cell M₂₁, and a sense amplifier SA₁, wherein the bit line BL₁ and the complementary bit line BLB₁ are the complementary bit lines of the sense amplifier SA₁.

According to some embodiments, a programming operation is performed on the first memory cell M₁₁ to configure the first memory cell M₁₁ as a programmed OTP memory cell. The second memory cell M₂₁ may be a non-programmed OTP memory cell during the programming operation of the first memory cell M₁₁. The capacitor C₂₁ of the second memory cell M₂₁ is not programed (or damaged), and functions similarly to a normal DRAM memory cell. Initially, the access transistor T₁₁ of the first memory cell M₁₁ is turned on by setting the gate voltage at the access voltage V_{PP} through the word line WL₁, while the access transistor T₂₁ of the second memory cell M₂₁ is kept turned off by setting the gate voltage at the about zero volts through the word line WL₂.

The sense amplifier SA₁ is then turned on and written with program data, where the voltage on the bit line (e.g., bit line BL₁) for a programed OTP memory cell is set as logic low state (logic ‘0’), while the voltage on the bit line for a non-programed memory cell is set at the logic high data (logic ‘1’). Thus, the voltages on the bit line BL₁ and the complementary bit line BLB₁ are set as the logic low state and logic high state, respectively, if the OTP memory cell on the bit line BL₁ is to be programed, while the voltages on the bit line BL₁ and the complementary bit line BLB₁ are set as the logic high state and logic low state, respectively, if the OTP memory cell on the bit line BL₁ is to be non-programed.

Subsequently, the array voltage V_{ARY} of the sense amplifier SA₁ is pulled from the normal voltage of about 1 to about 1.8 volts used for a normal operation to a higher voltage of about two volts for the programming operation. The pulled array voltage V_{ARY} should be controlled to be lower than the breakdown voltage of the transistors in the sense amplifier SA₁. Subsequently, the cell plate voltages V_{PLT} of the first memory cell M₁₁ and the second memory cell M₂₁ are pulled to a program voltage V_{PGM}, wherein the program voltage V_{PGM} is substantially equal to or greater than twice the array voltage V_{ARY} of the sense amplifier SA₁, for example, to be about four volts.

Referring to a right subfigure of FIG. 2, a plot of voltage differences on the electrically insulating layers of the capacitor C₁₁ is shown. Through the abovementioned voltage settings, in a first programming scenario where the memory cell M₁₁ is a programmed memory cell, the two electrodes of the capacitor C₁₁ may provide voltages of V_{PGM} and zero volts, respectively, on two sides of the insulating layer of the capacitor C₁₁. According to some embodiments, the voltage difference between V_{PGM} and zero volts, i.e., the program voltage V_{PGM}, is greater than the breakdown voltage of the electrically insulating layer of the capacitor C₁₁, and thus the program voltage V_{PGM} would cause breakdown of the electrically insulating layer of the capacitor C₁₁. Through the programming operation, a leakage path may be formed in the electrically insulating layer of the capacitor C₁₁ such that the capacitor C₁₁ is unable to retain charges. According to some embodiments, the leakage path formed by the programming operation is stable and permanent, and thus the programmed state of the memory cell M₁₁ can be regarded to be non-volatile.

Conversely, through the abovementioned voltage settings, in a second programming scenario where the memory cell M₁₁ is a non-programmed memory cell, the two electrodes of the capacitor C₁₁ may provide voltages of V_{PGM} and pulled V_{ARY}, respectively. According to some embodiments, the voltage difference between V_{PGM} and pulled V_{ARY}, i.e., about two volts, is less than the breakdown voltage of the electrically insulating layer of the capacitor C₁₁, and thus the program voltage V_{PGM} would not cause breakdown of the electrically insulating layer of the capacitor C₁₁. According to some embodiments, the electrically insulating layers of the memory cells Mₘₙ are substantially the same, and therefore the breakdown voltages of the insulating layers in different memory cells are substantially equal. During the programming operation, the electrically insulating layer of the capacitor C₁₁ in a non-programmed memory cell M₁₁ can still function properly such that the capacitor C₁₁ is still able to retain charges just like itself prior to the programming operation.

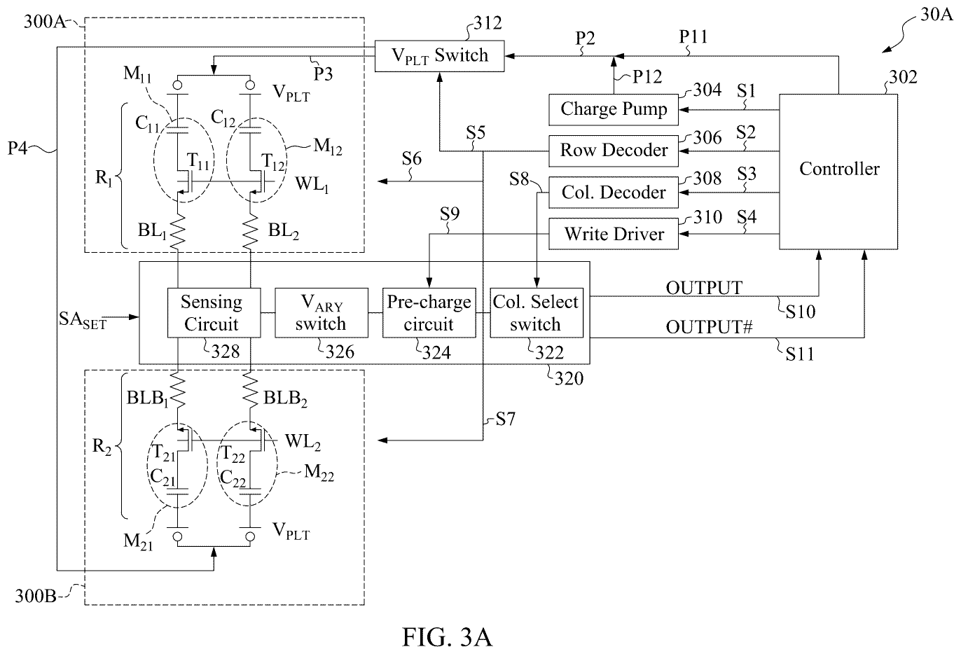

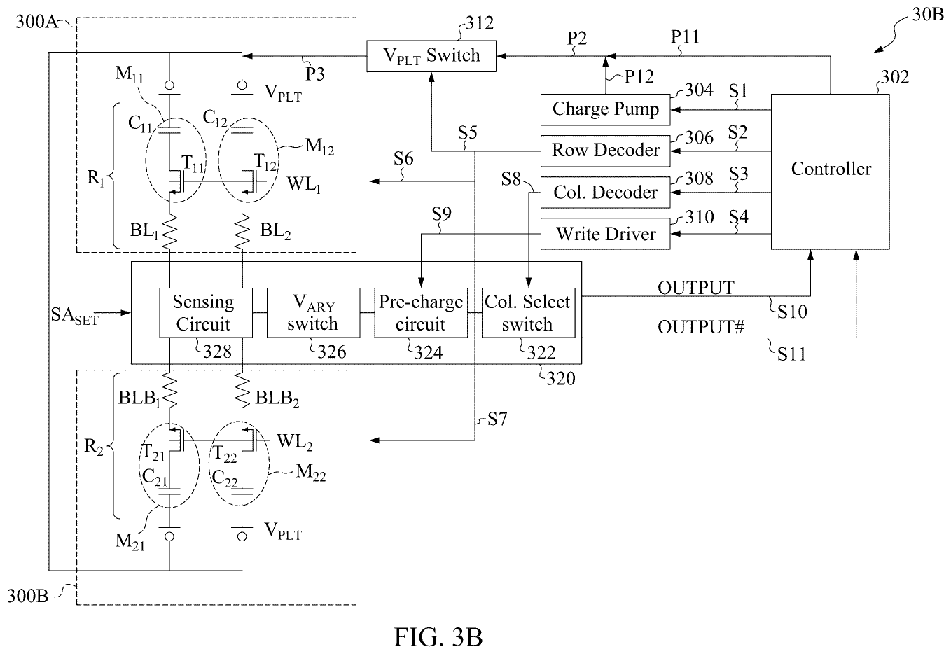

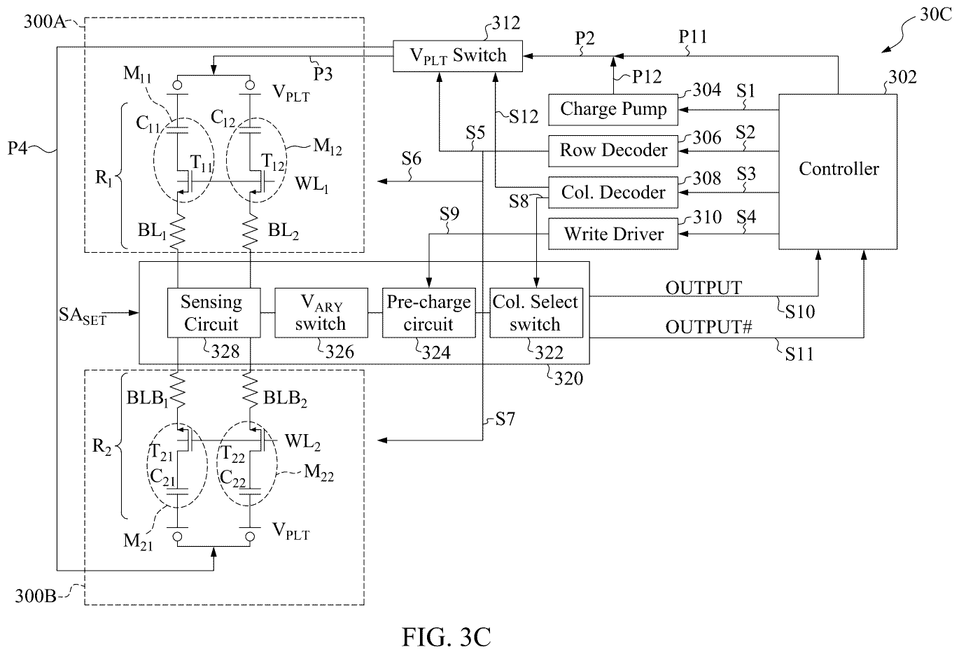

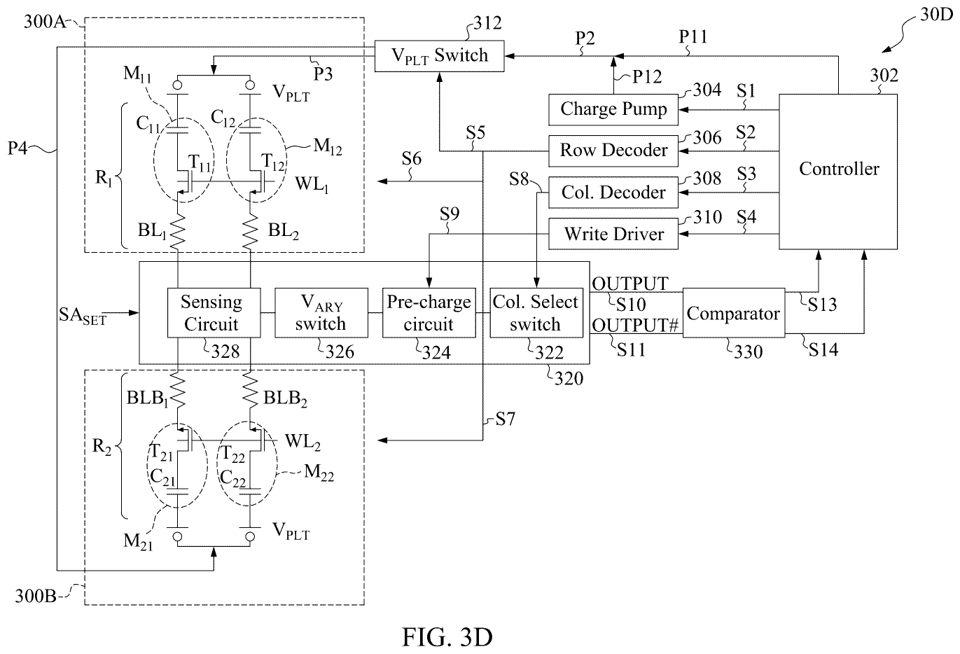

FIG. 3A is a schematic diagram of an OTP memory device 30A, in accordance with various embodiments of the present disclosure. The OTP memory device 30A includes a first OTP memory array 300A, a second OTP memory array 300B, a controller 302, a charge pump circuit 304, a row decoder 306, a column decoder 308, a write driver 310, a cell plate voltage (V_{PLT}) switch 312, and a sense amplifier 320. The sense amplifier 320 may include a column select switch 322, a pre-charge circuit 324, an array voltage switch V_{ARY} 326, and a sensing circuit 328. FIG. 3A only shows parts of the OTP memory device 30A for illustrative purposes, but the present disclosure is not limited thereto. More or less elements can be incorporated into or removed from the OTP memory device 30A.

According to some embodiments, the first memory cell 300A includes two example columns having respective example memory cell M₁₁ and M₁₂ on an example row R₁ accessed by a word line WL₁, wherein the memory cell M₁₁ includes a capacitor C₁₁ and an access transistor T₁₁ and the memory cell M₁₂ includes a capacitor C₁₂ and an access transistor T₁₂. Likewise, the second memory cell 300B includes two example columns having respective example memory cell M₂₁ and M₂₂ on an example row R₂ accessed by a word line WL₂, wherein the memory cell M₂₁ includes a capacitor C₂₁ and an access transistor T₂₁ and the memory cell M₂₂ includes a capacitor C₂₂ and an access transistor T₂₂. The two columns of the first memory array 300A are accessed by the respective bit lines BL₁ and BL₂, and the two columns of the second memory array 300B are accessed by the respective complementary bit lines BLB₁ and BLB₂.

According to some embodiments, the first memory array 300A or the second memory array 300B may be formed of one or more MATs, or formed of other units of memory, where the first memory array 300A and the second memory array 300B are shown in FIG. 3A for illustrative purposes. According to some embodiments, the first memory array 300A and the second memory array 300B belong to the same MAT or different MATs. The first memory array 300A and the second memory array 300B can be similar to MATs MAT₁ and MAT₂, respectively, shown in FIG. 1A or 1B, and the details of their descriptions are omitted for brevity. According to some embodiments, the first memory array 300A or the second memory array 300B can be configured as either a volatile (normal) DRAM memory array or a non-volatile (OTP) memory array.

According to some embodiments, the controller 302 is configured to perform transmission and receiving of memory data and control/command signals between the components of the OTP memory device 30A. According to some embodiments, the controller 302 is configured to perform a normal operation, including a reading operation and a writing operation, of a normal DRAM memory cell, and perform an OTP operation, including a programming operation and a reading (sensing) operation, of an OTP memory cell. Throughout the present disclosure, the normal operation refers to the reading operation, the writing operation, or both, of a normal DRAM memory cell, and the OTP operation refers to the programming operation, the reading operation, or both, of an OTP memory cell.

According to some embodiments, the controller 302 is configured to supply a cell plate voltage V_{PLT} of about 0.5 volts to the first memory array 300A and the second memory array 300B through a power line P11 for the normal operation of DRAM memory cells. According to some embodiments, the controller 302 is configured to supply a cell plate voltage V_{PLT} of about zero volts to the first memory array 300A and the second memory array 300B through the power line P11 for the OTP reading operation of OTP memory cells. A charge pump is, for example, a kind of DC-to-DC converter that generally uses capacitors for energetic charge storage to raise or lower an input voltage and generate a desired output voltage with relatively simple circuitry. According to some embodiments, the charge pump circuit 304 is configured to supply the V_{PLT} switch 312 with a cell plate voltage V_{PLT} of about 4 volts as an OTP programming voltage for an OTP programming operation of an OTP memory cell. According to some embodiments, the charge pump circuit 304 is configured to supply the V_{PLT} switch 312 with the array voltage V_{ARY} of about 1 volt to about 1.8 volts as an OTP reading voltage through a power line P12 for an OTP reading operation. According to some embodiments, the charge pump circuit 304 is replaced with an external power pin, which is configured to receive the predetermined cell plate voltage V_{PLT} as the OTP programming voltage or OTP reading operation from a power source external to the memory device 30A.

According to some embodiments, the controller 302 is configured to transmit a control/command signal OTP_PGM_PLT to the charge pump circuit 304 through a signal line S1 to enable the charge pump circuit 304 for an OTP programming operation. According to some embodiments, the controller 302 is configured to transmit a control/command signal OTP_READ_PLT to the charge pump circuit 304 through the signal line S1 to disable the charge pump circuit 304 for an OTP reading operation. The cell plate voltage V_{PLT} supplied by the controller 302 or the charge pump circuit 304 is transmitted from the power line P11 or P12, through the power line P2 and the V_{PLT} switch 312, and reaches the first memory array 300A and the second memory array 300B via the power lines P3 and P4, respectively.

According to some embodiments, the controller 302 is configured to transmit a row address carried by a row address signal to the row decoder 306 through a signal line S2. According to some embodiments, the row decoder 306 is configured to decode the row address and convert the row address into a row select signal for enabling the selected row in the first memory array 300A or the second memory array 300B. According to some embodiments, the row address signal is transmitted by the controller 302 through the signal line S2, and the row select signal is transmitted from the row decoder 306 to the V_{PLT} switch 312, the first memory array 300A and the second memory array 300B through signal lines S5, S6 and S7, respectively, for controlling the memory cells in the selected row are either activated or deactivated.

According to some embodiments, the controller 302 is configured to transmit a column address carried by a column address signal to the column decoder 308 through a signal line S3. According to some embodiments, the column decoder 308 is configured to decode the column address and convert the column address into a column select signal for enabling the selected column in the first memory array 300A or the second memory array 300B. According to some embodiments, the column address signal is transmitted by the controller 302 through the signal line S3, and the column select signal is transmitted from the column decoder 308 to the column select switch 322 in the sense amplifier 320 through a signal line S8. According to some embodiments, the controller 302 is configured to transmit an enable signal SA_{SET} to turn on the sense amplifier 320 prior to a normal operation or an otp operation of the memory device 30a.

According to some embodiments, the controller 302 is configured to transmit write data to the write driver 310 through a signal line S4 for a normal writing operation. According to some embodiments, the controller 302 is configured to transmit a control/command signal OTP_PGM_BL to enable the write driver 310 through the signal line S4 for an OTP programming operation. The controller 302 may provide the write driver 310 with program data, which correspond to the write data to be written into the memory cells, for an OTP programming operation. According to some embodiments, the controller 302 is configured to transmit a control/command signal OTP_READ_BL to the write driver 310 through the signal line S4 for performing an OTP reading operation. The controller 302 may provide the write data to the write driver 310 for sensing the logic states of the OTP memory cells in an OTP reading operation.

The controller 302 may be implemented by hardware, software, firmware, a combination thereof, or the like, and may be formed of a general-purpose computer, a memory controller, a central processing unit (CPU), a graphics processing unit (GPU), an application specific integrated chip (ASIC), a field programmable gate array (FPGA), a digital signal processor (DSP), a microcontroller, or the like.

According to some embodiments, the write driver 310 is configured to cause the complementary bit line pair in the pre-charge circuit 324 to be pulled up to a pre-charge voltage, e.g., one half of array voltage V_{ARY}, through a signal line S9 for a normal operation or an OTP operation. The write driver 310 may provide the write data or program data to the pre-charge circuit 324 through the signal line S9 to thereby enable a normal writing operation, an OTP reading operation, or an OTP programming operation.

According to some embodiments, the array voltage V_{ARY} switch 326 is configured to modulate the voltages of the logic high state data on the bit lines BL₁, BL₂ or the complementary bit lines BLB_{1,} BLB₂ from a normal voltage, e.g., from about 1 volts to about 1.8 volts, to about two volts, to thereby enable an OTP reading operation or an OTP programming operation, and keep the voltages of the logic low state data on the bit lines BL₁, BL₂ or the complementary bit lines BLB₁, BLB₂ as about zero volts. According to some embodiments, the array voltage V_{ARY} switch 326 is implemented by a voltage conversion circuit to convert a voltage from other components of the memory device 30A. According to some embodiments, the array voltage V_{ARY} switch 326 includes a charge pump or received the modulated array voltage V_{ARY} of about two volts from the charge pump 304.

According to some embodiments, the sensing circuit 328 is configured to sense (read) the data of the memory cells in the first memory array 300A or the second memory array 300B for a normal reading operation or an OTP reading operation. The sensing circuit 328 may include a number of sense amplifiers (not separately shown), each connected to the corresponding pair of complementary bit line pairs, e.g., the pair of bit lines BL₁ and BLB₁ or the pair of bit lines BL₂ and BLB₂. The outputs of the sensing circuit 328 or the sense amplifier 320 may include a pair of complementary data in a digital form, i.e., a pair of complementary output data bits denoted by labels “output” and “output #”, which are referred to as initial logic states and are transmitted to the controller 302 through signal lines S10 and S11, respectively.

Referring to FIG. 3A, the rows R₁ and R₂ may refer to different rows disposed in respective memory arrays 300A and 300B, and the cell plate voltages V_{PLT} in the different rows R₁ and R₂ can be controlled according to their row addresses provided by the V_{PLT} switch 312 through respective power lines P3 and P4. Thus, the memory cells M₁₁, M₁₂ and the memory cells M₂₁, M₂₂ arranged in different rows R₁ and R₂ or in different columns are separately controllable. The cell plate or capacitor nodes of the OTP memory cells can be programmed separately.

Further, in existing DRAM memory devices, the cell plate voltage V_{PLT} is kept substantially equal as about zero or 0.5 volts for the normal operation. Therefore, the cell plates or capacitor nodes of all the rows across different memory arrays or MATs are usually shorted together to simplify circuit design. The charging speed of the cell plate voltage V_{PLT} may be relatively low since the number of the memory cells to be charged is quite large. In contrast, the proposed separate programming scheme causes the charging of the cell plate voltages V_{PLT} to be performed separately for different rows or columns. Thus, since the number of the memory cells to be charged by the charge pump circuit 304 at the same time is reduced due to separate charging of the cell plate voltages V_{PLT} in different rows or columns, the capacitive loading is reduced, and the charging speed of the cell plate voltage V_{PLT} is improved accordingly.

FIG. 3B is a schematic diagram of an OTP memory device 30B, in accordance with various embodiments of the present disclosure. The OTP memory device 30B is similar to the OTP memory device 30A in many aspects, and descriptions of these similar aspects are not repeated for brevity. The OTP memory device 30B is different from the OTP memory device 30A in that the rows R₁ and R₂ are grouped together to form a row group and supplied by the same source of cell plate voltage V_{PLT} through the common power line P3. The cell plate voltages V_{PLT} of the rows R₁ and R₂ are shorted. The design complexity of the control circuit for the OTP memory device 30B can be reduced as compared to that of the OTP memory device 30A. According to some embodiments, although not separately shown, the rows in different row groups are still controllable separately through a separate control scheme of the cell plate voltages V_{PLT} for different row groups. Thus, since the number of the memory cells to be charged by the charge pump circuit 304 is reduced due to separate control of the cell plate voltages V_{PLT} in different rows, the capacitive loading is reduced, and the charging speed of the cell plate voltage V_{PLT} is improved accordingly. The OTP memory device 30B can provide the cell plate voltages V_{PLT} with an alternative tradeoff than the OTP memory device 30A between the charging speed and design complexity.

FIG. 3C is a schematic diagram of an OTP memory device 30C, in accordance with various embodiments of the present disclosure. The OTP memory device 30C is similar to the OTP memory device 30A in many aspects, and descriptions of these similar aspects are not repeated for brevity. The OTP memory device 30C is different from the OTP memory device 30A in that the column decoder 308 is configured to provide a column select signal through a signal line S12, similar to the signal S8, to the V_{PLT} switch 312 to thereby enable column-wise separate control of the cell plate voltages V_{PLT}. According to some embodiments, the columns are separately controlled in a minimal unit of one MAT. Thus, memory cells in different MATs along the row direction of the OTP memory device 30C can be controlled separately by the V_{PLT} switch 312. In view of the above, since the number of the memory cells to be charged by the charge pump circuit 304 is further reduced due to separate control of the cell plate voltages V_{PLT} in different rows and MAT columns, the capacitive loading is reduced a step further, and the charging speed of the cell plate voltage V_{PLT} can be improved as compared to the OTP memory device 30A.

FIG. 3D is a schematic diagram of an OTP memory device 30D, in accordance with various embodiments of the present disclosure. The OTP memory device 30D is similar to the OTP memory device 30A in many aspects, and descriptions of these similar aspects are not repeated for brevity. The OTP memory device 30D is different from the OTP memory device 30A in that the OTP memory device 30D further includes a comparator 330 between the sense amplifier 320 and the controller 302. The comparator 330 is configured to receive the output data bits “output” and “output #” (i.e., initial logic states) of the sensing circuit 328 in the sense amplifier 320 in a normal reading operation or an OTP reading operation, and provide logic states of modulated OTP output data bits denoted by labels “OTP_STATE” and “OTP_STATE #” (which are referred to as final logic states), to the controller 302.

The voltage values discussed with reference to FIGS. 1A, 1B, 2, and other figures in the present disclosure are provided for illustrative purposes. The actual voltage values may be adjusted based on different factor including the circuit design, the manufacturing processes and other requirements.

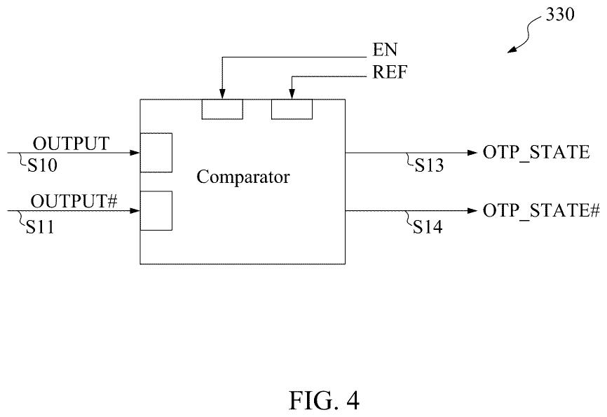

FIG. 4 is a schematic diagram of the comparator 330 of the OTP memory device 30D, in accordance with various embodiments of the present disclosure. The comparator 330 includes two input ports configured to receive the data bits on the signal lines S10 and S11, i.e., the complementary data bits of “output” and “output #” provided by the sense amplifier 320. The comparator 330 further includes two output ports configured to provide the controller 302 with the logic states of the modulated complementary OTP data bits “OTP_STATE” and “OTP_STATE #” for the normal reading operation or the OTP reading operation through signal lines S13 and 14, respectively.

Moreover, the comparator 330 may further include an enable signal port configured to receive an enable signal “EN” from the controller 302 to turn on the comparator 330. The OTP memory device 30D may be configured to perform a normal DRAM operation in the absence of the enable signal “EN.” According to some embodiments, the comparator 330 also include a reference signal port configured to receive a reference signal “REF” from the controller 302 for performing data comparison. According to some embodiments, the reference signal “REF” includes the value of a bit line pre-charge voltage V_{BLP}, which is a value of about one half of the logic high stage (‘1’), e.g., about 0.5 volts.

According to some embodiments, data or charges stored in the capacitor Cₘₙ of the non-programmed memory cell Mₘₙ can last for a predetermined period of data retention time. The charges may gradually leak to the substrate of the memory device. After the period of data retention time, the charges in the memory cell will be lost and the data in the memory cell is read as a logic low bit (‘0’) no matter which logic state was initially stored therein. Further, for a programmed memory cell Mₘₙ, the charges will leak through the leakage path within a data retention time much shorter than that of the non-programmed memory cell Mₘₙ. Based on the above observation, the data bits of the programmed memory cell Mₘₙ and the non-programmed memory cell Mₘₙ can be differentiated through their different lengths of data (charge) retention time periods. For example, the data retention time, of the programmed memory cell Mₘₙ. is much less than about 64 milliseconds (ms), e.g., in a range of several microseconds (μs), while the data retention time, of the non-programmed memory cell Mₘₙ. is substantially equal to or greater than about 64 ms.

Therefore, in a first option of the proposed OTP reading operation, the cell plates or capacitor nodes of the memory cells are set to about zero volts, and the memory cells are written with data of logic high states and accessed after a predetermined waiting time T_{R}. The predetermined waiting time T_{R} of time is thus set as a waiting time in a time range shorter than the data retention time of the non-programmed memory cells and longer than the data retention time of the programmed memory cells. Alternatively, the predetermined waiting time T_{R} is set as the data retention time of a normal DRAM memory cell before it is subjected to an OTP programming operation. Thus, the predetermined waiting time T_{R} is set as substantially equal to or greater than about 64 ms. Once the logic high state data are written to both the programmed and non-programmed memory cells and after the waiting time T_{R}, the non-programmed memory cell Mₘₙ. would keep the charges in the capacitor Cₘₙ, while the programmed memory cell Mₘₙ would lose the charges in the capacitor Cₘₙ. In other words, the memory cell Mₘₙ with a readout data bit of logic low state is determined to be a programmed memory cell Mₘₙ, and the memory cell Mₘₙ with a readout data bit of logic high state is determined to be a non-programmed memory cell Mₘₙ.

According to some embodiments, in a second option of the proposed OTP reading operation, the cell plates or capacitor nodes of the memory cells are set to the array voltage V_{ARY}, and logic low state data are written to both the programmed and non-programmed memory cells and after the waiting time T_{R}, the intact status of the electrically insulating layer of the non-programmed memory cell Mₘₙ will cause the non-programmed memory cell Mₘₙ. to keep the logic low state (i.e., the low voltage of about zero volts) of the capacitor Cₘₙ, and the damaged status of the electrically insulating layer of the programmed memory cell Mₘₙ will cause the programmed memory cell Mₘₙ or the sensing bit line BLₙ to be charged with the cell plate with the array voltage V_{ARY}. In other words, the data sensing result using the second option of proposed alternative reading operation will determine the memory cell Mₘₙ with a readout data bit of logic high state to be a programmed memory cell, and determine the memory cell Mₘₙ with a readout data bit of logic low state to be a non-programmed memory cell Mₘₙ.

Based on the above principle, the OTP reading operation incorporating the comparator 330 can be performed by comparing one or both of the pair of complementary output data bits “output” and “output #” with the reference signal “REF” and provide the logic states of the pair of modulated OTP output data bits “OTP_STATE” and “OTP_STATE #” on the signal line S13 and S14. When the reading scheme of the first option is adopted, the memory cell Mₘₙ with an output data bit of logic low state is determined to be a programmed memory cell Mₘₙ, and the memory cell Mₘₙ with an output data bit of logic high state is determined to be a non-programmed memory cell Mₘₙ. Conversely, when the reading scheme of the second option is adopted, the memory cell Mₘₙ with an output data bit of logic low state is determined to be a non-programmed memory cell Mₘₙ, and the memory cell Mₘₙ with an output data bit of logic high state is determined to be a programmed memory cell Mₘₙ. According to some embodiments, the programmed memory cell Mₘₙ and the non-programmed memory cell Mₘₙ are mapped to the logic high state and the logic low state of the memory cell Mₘₙ, respectively, based on some design requirements. Alternatively, the programmed memory cell Mₘₙ and the non-programmed memory cell Mₘₙ are mapped to the logic low state and the logic high state of the memory cell Mₘₙ, respectively, based on other design requirements.

According to some embodiments, the logic states of the modulated OTP data bits “OTP_STATE” and “OTP_STATE #” are detected based on direct estimation of the data retention time of the memory cells Mₘₙ of interest. As discussed previously, the data bits of the programmed memory cell Mₘₙ. and the non-programmed memory cell Mₘₙ. can be differentiated through their different lengths of data (charge) retention time periods. Thus, the writing data of logic high state data or logic low state data are written to both the programmed and non-programmed memory cells. The comparator 330 is configured to estimate the data retention time of the memory cells, which is the voltage falling time from the logic high state (e.g., at the voltage of about one volt) to the logic low state (e.g., at the voltage of about zero volts), or the voltage raising time from the logic low state (e.g., at the voltage of about zero volt) to the logic high state (e.g., at the voltage of about one volt). The data included in the reference signal “REF” is set as a time period, e.g., about 64 ms, between the data retention time of the non-programmed memory cell and the data retention time of the programmed memory cell. If the estimated voltage falling time or voltage raising time is substantially equal to or greater than the reference signal “REF,” then the memory cell is determined to be a non-programmed memory cell. Conversely, if the estimated voltage falling time is less than the reference signal “REF,” then the memory cell is determined to be a programmed memory cell.

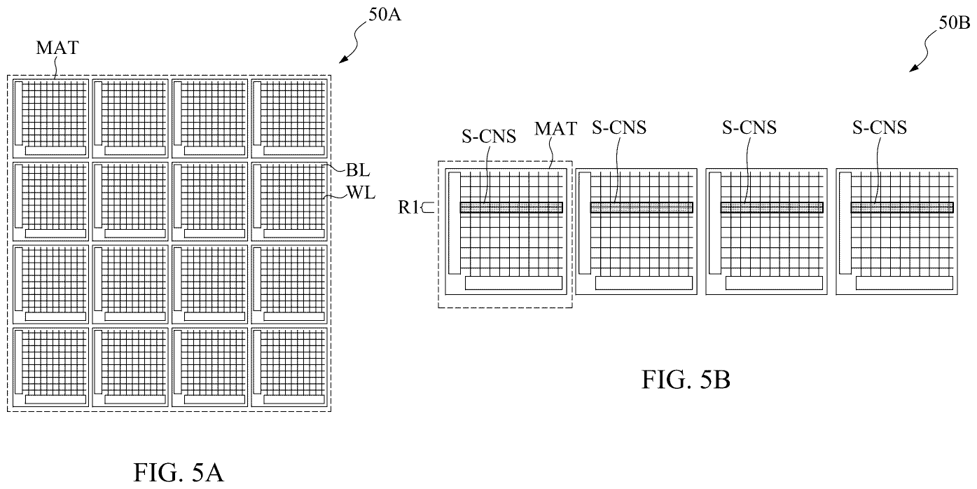

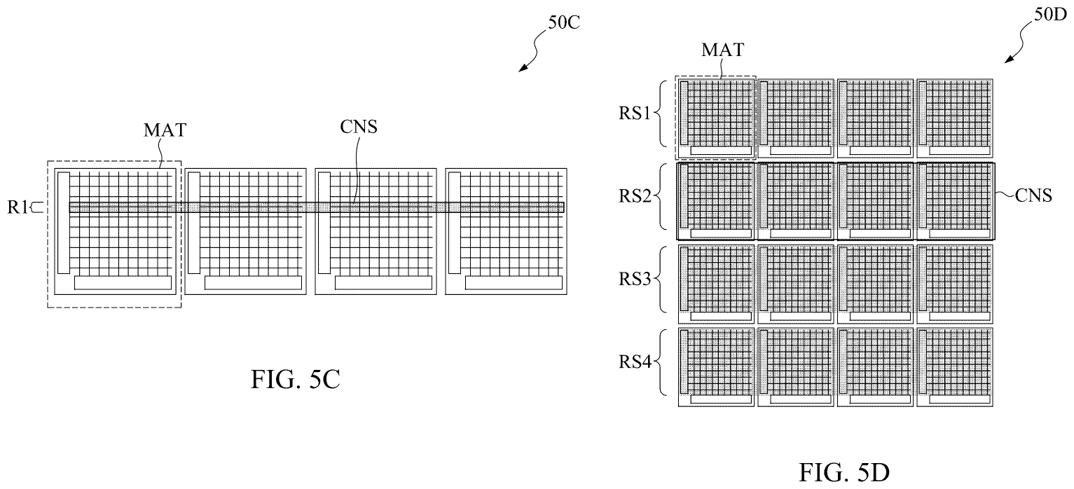

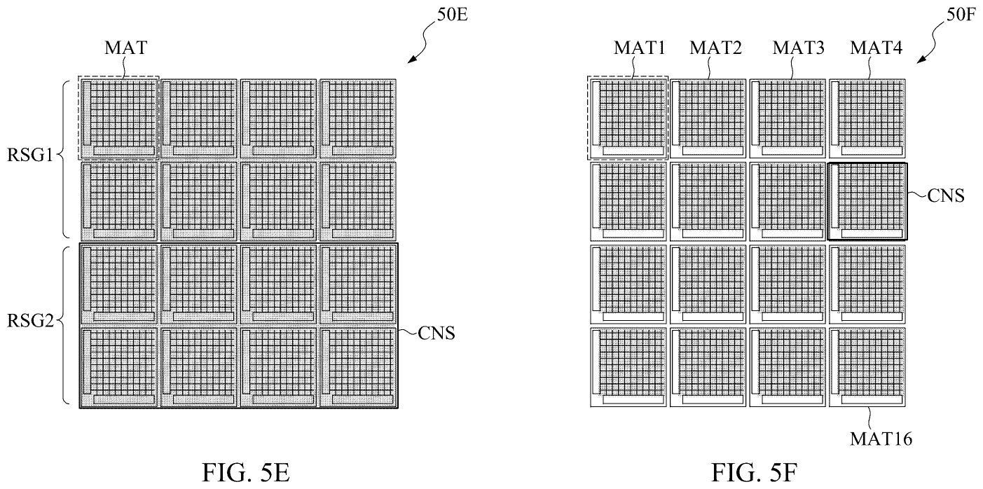

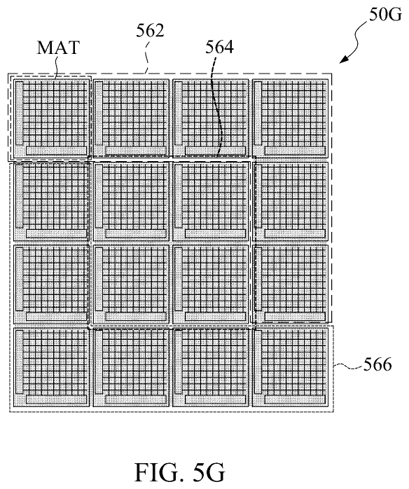

FIGS. 5A, 5B, 5C, 5D, 5E, 5F and 5G are schematic diagrams of OTP memory devices 50A, 50B, 50C, 50D, 50E, 50F and 50G, respectively, in accordance with various embodiments of the present disclosure. According to some embodiments, the memory devices 50A to 50G have the same size, e.g., a memory bank formed of 16 MATs (denoted by constituent blocks in FIGS. 5A to 5G), although FIGS. 5B and 5C show only part of the memory bank. The memory devices 50A to 50G also have many features of a DRAM-based OTP memory array similar to those shown in FIGS. 1A and 1B, although these features are omitted from FIGS. 5A to 5G. The memory device 50A illustrated in FIG. 5A is shown to include a reference configuration without any grouping, e.g., each MAT includes a plurality of word lines (WL) extending in the horizontal direction and a plurality of bit lines (BL) extending in the vertical direction. A memory cell (not separately shown) is formed on each cross point of the word lines and bit lines. The main difference among the memory devices 50B to 50G is the group size difference in the memory devise 50B to 50G, in which each group is defined as an area of the memory cells and each of the groups is separately controllable.

Referring to FIG. 5B, the block indicated by a row R1 shown in each MAT of the memory device 50B is referred to as a “sub-capacitor node segment (S-CNS)” or simply “sub-node segment,” which indicates that the cell plate voltages V_{PLT} (capacitor nodes) of the row R1 in each of the MATs of the row R1 are shorted to form a group. Thus, each S-CNS includes only a width of one row of word lines and a length of one MAT. In other words, all of the capacitor nodes of the memory device 50B along the column direction are divided into several S-CNSs in the corresponding rows, in which at least two of the different S-CNSs are separately controllable. Further, all of the capacitor nodes of the memory device 50B along the row direction are divided into several S-CNSs in the corresponding MATs along the row direction, in which at least two of the S-CNS in different MATs are separately controllable. Each of the S-CNSs includes the capacitor nodes of the memory cells along one of the several rows, or along one of the several word lines, within one MAT. The capacitive loading of each group of the memory device 50B is greatly reduced as compared to a single-group memory device, such as the memory device 50A.

Referring to FIG. 5C, the block indicated by the row R1 and extending across all of the horizontal MATs (e.g., four MATs) of the memory device 50C is referred to as “capacitor node segment (CNS),” which indicates that the cell plate voltages V_{PLT} (capacitor nodes) of the row R1 across multiple (e.g., four) MATs in the row direction are shorted to form a group. Thus, each CNS includes only a width of one row of word lines and a length of multiple MATs. In other words, all of the capacitor nodes of the memory device 50C along the column direction are divided into several CNSs in the respective rows of multiple MATs in the row direction, in which at least two of the CNSs are separately controllable. Each of the CNSs includes the capacitor nodes of the memory cells along one of the several rows, or along one of the several word lines. According to some embodiments, referring to FIGS. 5B and 5C, each CNS include a plurality of S-CNSs along the row direction. The complexity of circuit design of the memory device 50C is lower with a greater capacitive loading of each group as compared to the memory device 50B.

Referring to FIG. 5D, each block in the memory device 50D with a length of multiple (e.g., four) MATs and a width of one MAT is referred to as a CNS, which indicates that the cell plate voltages V_{PLT} of row segment RS1, RS2, RS3 or RS4 across the multiple MATs are respectively shorted to form a group. The row segment RS1 to RS4 are defined as a segment of rows with a width of one MAT in the column direction and a length of multiple MATs in the row direction. Thus, each CNS of the memory device 50D includes a row segment, e.g., row segment RS1, RS2, RS3 or RS4, with a length of multiple MATs. In other words, all of the capacitor nodes of the memory device 50D along the column direction are divided into several CNSs in the corresponding row segments, in which at least two of the different CNSs are separately controllable. Each of the CNSs includes the capacitor nodes of the memory cells along one MAT row, or along one row of the several MATs. The complexity of circuit design of the memory device 50D is lower with a greater capacitive loading of each group as compared to the memory device 50B or 50C.

Referring to FIG. 5E, each block in the memory device 50E with a length of multiple (e.g., four) MATs and a width of a row segment group RSG1 or RSG2, equal to multiple (e.g., two) MATs, is referred to a CNS, which indicates that the cell plate voltages V_{PLT} (capacitor nodes) of the row segment group RSG1 or RSG2 across multiple MATs are shorted. Thus, each CNS of the memory device 50E includes respective row segment groups RSG1 or RSG2 with multiple (e.g., two) rows of MATs. In other words, all of the capacitor nodes of the memory device 50E along the column direction are divided into several CNSs in the corresponding RSGs, in which at least two of the different RSGs are separately controllable. Each of the CNSs includes the capacitor nodes of the memory cells in two MAT rows, or in two rows of several MATs. The complexity of circuit design of the memory device 50E is lower with a greater capacitive loading of each group as compared to the memory device 50B, 50C or 50D.

Referring to FIG. 5F, each block with a length of one MAT and a width of one MAT indicates that the cell plate voltages V_{PLT} (capacitor nodes) of each single MAT are shorted. Thus, each CNS of the memory device 50F includes respective MAT, i.e., MAT1, MAT2, MAT3, MAT4, . . . MAT16. The complexity of circuit design and the capacitive loading of the memory device 50F may be between the lowest one and the highest one as compared to the memory devices 50B, 50C, 50D and 50E. Further, the grouping method of the memory devices 50B and 50F provides another direction of grouping by partitioning the memory bank into different MAT columns. In other words, all of the capacitor nodes of the memory device 50F along the row and column directions are divided into several CNSs in the corresponding MATs, in which at least two of the CNSs are separately controllable. Each of the CNSs includes the capacitor nodes of the memory cells along the word lines in the respective MAT. Each of the CNSs includes the capacitor nodes of the memory cells within one MAT. The complexity of circuit design and the capacitive loading of the memory device 50F may be between the lowest one and the highest one of the memory devices 50B, 50C, 50D and 50E.

Referring to FIG. 5G, the MATs of the memory device 50G are grouped by partitioning the MATs into CNSs of non-regular shapes. The memory device 50G includes a first CNS 562, a second CNS 564 and a third CNS 566, wherein the first CNS 562 and the third CNS 566 are formed of six MATs and arranged in an L-shape. The second CNS 564 is formed of four MATs and arranged in a square shape. In other words, all of the capacitor nodes of the memory device 50G are divided into several CNSs in the corresponding MAT groups, in which at least two of the CNSs are separately controllable. The capacitive loading of the first CNS 562 and the third CNS 566 may be different from that of the second CNS 564 due to different number of memory cells (or MATs). The complexity of circuit design of the memory device 50G may be greater as compared to the previous memory devices 50B to 50F. According to some embodiments, the capacitive loading of the second CNS 564 may be lower than the first CNS 562 and the third CNS 566 because of the less total number of the capacitor nodes for the second CNS 564. The second CNS 564 may provide faster OTP programming speed and reading speed, and may be used to store the data or information for different purposes or requirements as compared with the first CNS 562 and the second CNS 566.

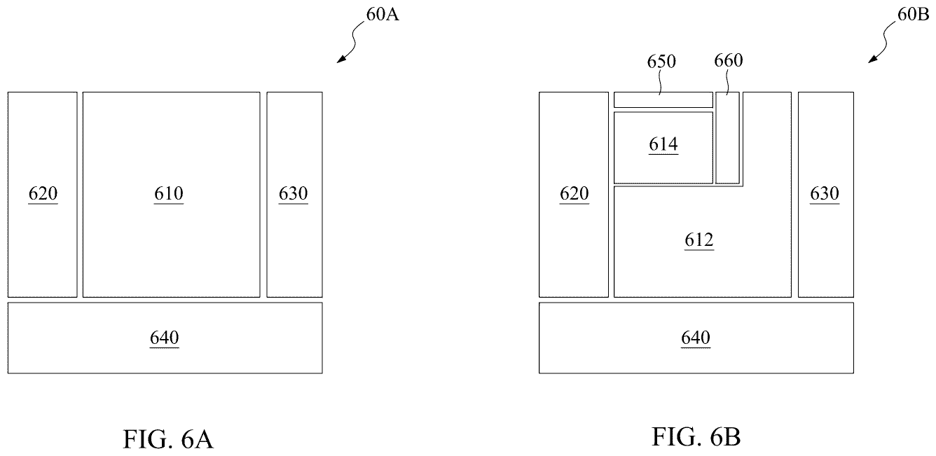

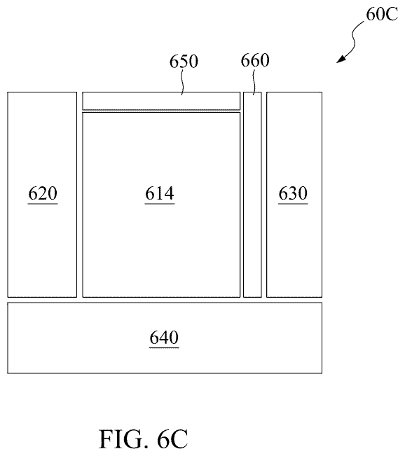

FIG. 6A is a schematic diagram of a memory device 60A, in accordance with various embodiments of the present disclosure. The memory device 60A includes a plurality of functional blocks, e.g., a memory array 610, a command interface 620, an input/output (I/O) circuit 630, and a peripheral circuit 640. According to some embodiments, the memory array 610 includes memory cells for used as either normal DARM memory cells or DRAM-based OTP memory cells. The memory array 610 may be partitioned into a first portion for the DRAM memory cells and a second portion for the DRAM-based OTP memory cells. The memory array 610 may be disposed between the command interface 620, the I/O circuit 630 and the peripheral circuit 640.

FIG. 6B is a schematic diagram of a memory device 60B, in accordance with various embodiments of the present disclosure. The functional blocks of the memory device 60B are similar to those of the memory device 60A, except that the memory array 610 of the memory device 60B is further partitioned into a DRAM array 612 and an OTP memory array 614. The DRAM array 612 and the OTP memory array 614 are formed on the same die, the same substrate, or the same wafer. The memory cells in the DRAM array 612 and the OTP memory array 614 have the same or similar cell structures, e.g., each memory cell includes one capacitor and one access transistor electrically coupled to the capacitor, as shown in FIGS. 1A and 1B. The difference between the DRAM array 612 and the OTP memory array 614 is that in the OTP memory array 614 the memory cells are partitioned into groups and the cell plate voltages V_{PLT} within each group are shorted, wherein each group is controllable separately. According to some embodiments, the cell plates or capacitor nodes of the capacitors (storage nodes) of the DRAM memory array 612 and the OTP memory array 614 are separately controllable. Further, the cell plates or capacitor nodes of the capacitors of different groups of rows, row segments, row segment groups, or MATs, of the OTP memory array 614 are separately controllable.

Further, according to some embodiments, the memory device 60B also includes a charge pump block 650. The charge pump block 650 may be used to include the charge pump circuit 304 shown in FIGS. 3A to 3D. According to some embodiments, the memory device 60B may further includes a comparator block 660. The comparator block 660 may be used to include the comparator 330 shown in FIGS. 3D and 4. According to some embodiments, the charge pump block 650 and the comparator block 660 are disposed adjacent to the OTP memory array 614.

FIG. 6C is a schematic diagram of a memory device 60C, in accordance with various embodiments of the present disclosure. The functional blocks of the memory device 60C are similar to those of the memory device 60A or 60B, except that the memory array of the memory device 60C is partitioned into the OTP memory array 614. That means the entire memory array is configured as the DRAM-based OTP memory. According to some embodiments, the memory device 60C may further includes the charge pump block 650 and the comparator block 660.

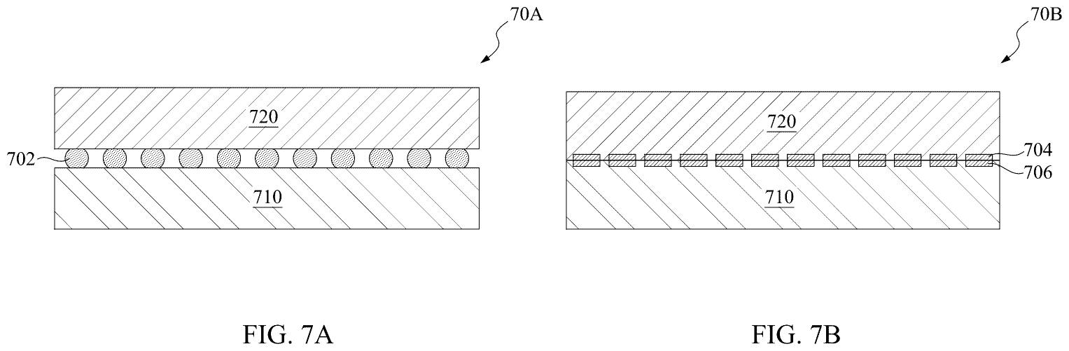

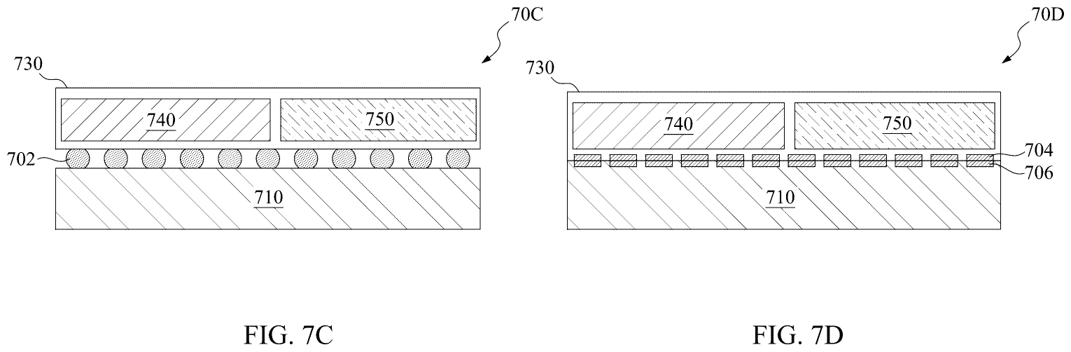

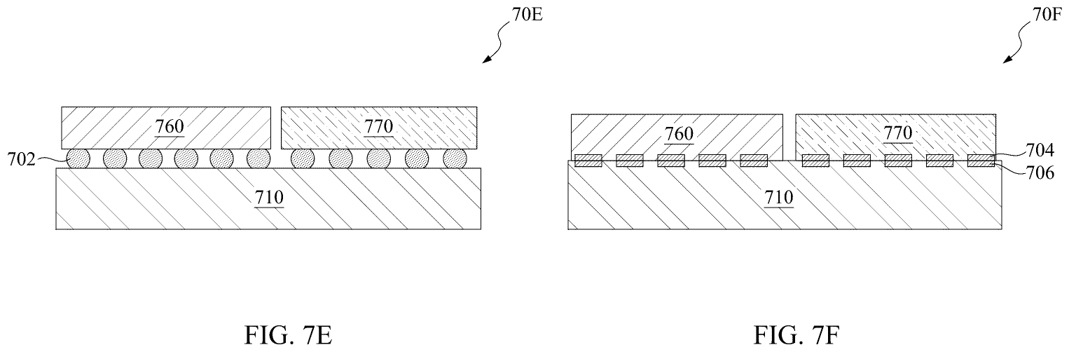

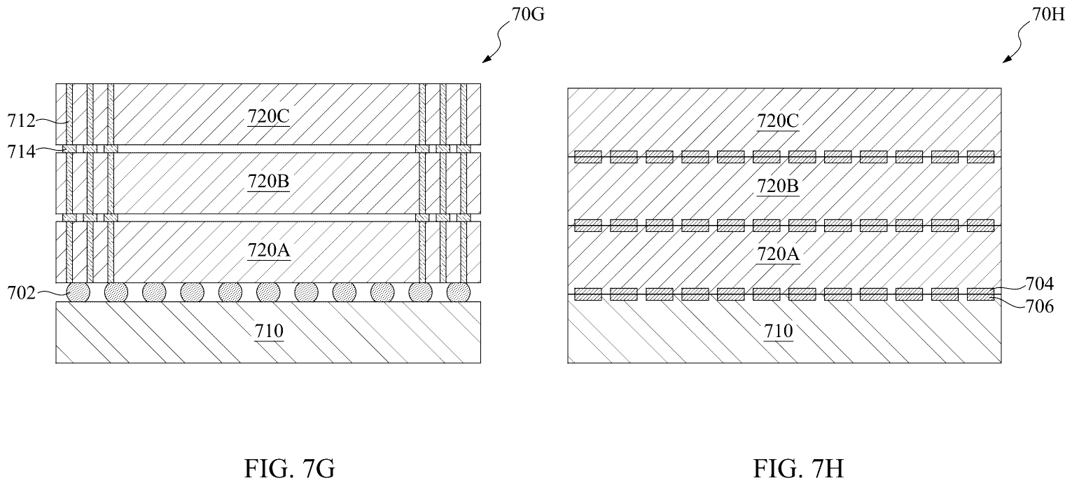

FIG. 7A is a schematic diagram of a semiconductor package 70A, in accordance with various embodiments of the present disclosure. The semiconductor package 70A includes a first die 710 or wafer, and a second die 720 or wafer stacking on the first die 710.

According to some embodiments, the first die 710 or wafer includes a logic die. The first die 710 or wafer may include a first substrate and a plurality of logic devices or circuits formed on/in the first substrate. According to some embodiments, the first die 710 may include memory controller, central processing unit (CPU), graphical processing unit (GPU), neural processing unit (NPU), tensor processing unit (TPU), or other processing units. According to some embodiments, the second die 720 is a memory die including the DRAM-based OTP memory cells. The second die 720 or wafer may include a second substrate, wherein the second die 720 further includes a DRAM-based OTP memory device including a plurality of DRAM-based OTP memory cells described with reference to previous figures and formed in/on the second substrate. According to some embodiments, capacitor nodes of the DRAM-based OTP memory cells in the DRAM-based OTP memory device are separately controllable.

According to some embodiments, the semiconductor package 70A further includes a plurality of interconnection nodes 702 disposed between and electrically connecting the first die 710 and the second die 720. The interconnection nodes 702 may be formed to electrically connect the first die 710 and the second die 720 by micro-bumping or nano-bumping. The first die 710 and the second die 720 may be bonded via wafer-on-wafer bonding or chip-on-wafer bonding. The interconnection nodes 702 may be formed of conductive materials, such as a solder material. The number of interconnection nodes 702 is significantly greater than that of existing DRAM devices or high-bandwidth memory (HBM) devices, by a factor of approximately ten to one hundred. According to some embodiments, the number of the interconnection nodes 702 exceeds about 10,000.

FIG. 7B is a schematic diagram of a semiconductor package 70B, in accordance with various embodiments of the present disclosure. The semiconductor package 70B is similar to the semiconductor package 70A in many features, and thus descriptions of these similar features are not repeated for brevity. The semiconductor package 70B is different from the semiconductor package 70A in that the semiconductor package 70B includes a plurality of interconnections 704 and 706 disposed on bonding surfaces of the first die 710 and the second die 720, respectively, between the first die 710 and the second die 720, and bonded together to electrically connect the first die 710 and the second die 720. The first die 710 and the second die 720 may be bonded via wafer-on-wafer bonding or chip-on-wafer bonding. The interconnection nodes 704 and 706 may be formed to electrically connect the first die 710 and the second die 720 by hybrid-bonding. For example, the interconnection nodes 704 may be aligned with the corresponding interconnection nodes 706, wherein the interconnection nodes 704 and 706 are bonded, e.g., via copper-copper bonding. Further, the first die 710 and second die 720 include dielectric layers (e.g., oxide) adjacent to the respective interconnection nodes 704 and 706 and are bonded together, e.g., via oxide-oxide bonding. The interconnection nodes 704 and 706 may be formed of conductive materials, such as copper or other suitable metallic materials. According to some embodiments, the number of the interconnection nodes 704 or 706 exceeds about 10,000.

FIG. 7C is a schematic diagram of a semiconductor package 70C, in accordance with various embodiments of the present disclosure. The semiconductor package 70C is similar to the semiconductor package 70A in many features, and thus descriptions of these similar features are not repeated for brevity. The semiconductor package 70C is different from the semiconductor package 70A in that the semiconductor package 70C includes the first die 710 or wafer, and a third die 730 or wafer stacking over the first die 710. According to some embodiments, the third die 730 is a memory die including a first memory region 740 and a second memory region 750.

According to some embodiments, the first memory region 740 is a DRAM-based OTP memory die including DRAM-based OTP memory cells. The first memory region 740 may include a fourth substrate and a plurality of DRAM-based OTP memory cells formed in/on the fourth substrate.

According to some embodiments, the second memory region 750 is a DRAM die including DRAM memory cells. The second memory region 750 may include a fifth substrate and a plurality of DRAM memory cells formed in/on the fifth substrate. According to some embodiments, the first memory region 740 and the second memory region 750 share the same substrate.

FIG. 7D is a schematic diagram of a semiconductor package 70D, in accordance with various embodiments of the present disclosure. The semiconductor package 70D is similar to the semiconductor packages 70B and 70C in many features, and thus descriptions of these similar features are not repeated for brevity. The semiconductor package 70D can be seen as a combination of the semiconductor packages 70B and 70C, in which the semiconductor package 70D includes the first die 710 or wafer and the third die 730 or wafer stacking over the first die 710. The third die 730 includes the first memory region 740 and the second memory region 750, in which the first memory region 740 is a DRAM-based OTP memory region and the second memory region 750 is a DRAM memory region. The third die 730 also includes an encapsulating material 732 encapsulating the first memory region 740 and the second memory region 750. The semiconductor package 70D may further include a plurality of interconnection nodes 704 and 706 disposed on bonding surfaces of the first die 710 and the third die 730, respectively, and bonded together to electrically connect the first die 710 and the third die 730.

FIG. 7E is a schematic diagram of a semiconductor package 70E, in accordance with various embodiments of the present disclosure. The semiconductor package 70E is similar to the semiconductor packages 70A and 70C in many features, and thus descriptions of these similar features are not repeated for brevity. The semiconductor package 70E can be seen as a combination of the semiconductor packages 70A and 70C, in which the semiconductor package 70E includes the first die 710 or wafer, the fourth die 760 stacking over the first die 710, and the fifth die 770 stacking over the first die 710 adjacent to the fourth die 760. According to some embodiments, the fourth die 760 is a DRAM-based OTP memory region and the fifth die 770 is a DRAM memory region. The semiconductor package 70E further includes a plurality of interconnection nodes 702 disposed between and electrically connecting the first die 710 and each of the fourth die 760 and the fifth die 770.

FIG. 7F is a schematic diagram of a semiconductor package 70F, in accordance with various embodiments of the present disclosure. The semiconductor package 70F is similar to the semiconductor packages 70B and 70D in many features, and thus descriptions of these similar features are not repeated for brevity. The semiconductor package 70F can be seen as a combination of the semiconductor packages 70B and 70D, or can alternatively be seen as an alternative of the semiconductor package 70E, in which the interconnection nodes 702 of the semiconductor package 70E are replaced with interconnection nodes 704 and 706. The interconnection nodes 704 are disposed on bonding surfaces of the fourth die 760 and the fifth die 770, while the interconnection nodes 706 are disposed on the bonding surface of the first die 710.

FIG. 7G is a schematic diagram of a semiconductor package 70G, in accordance with various embodiments of the present disclosure. The semiconductor package 70G is similar to the semiconductor package 70A in many features, and thus descriptions of these similar features are not repeated for brevity. The semiconductor package 70G is different from the semiconductor package 70A in that the semiconductor package 70G includes a plurality of second dies 720, e.g., second dies 720A, 720B and 720C stacking over one another. Each of the second dies 720 may include through silicon vias 712 extending through the thickness of the second dies 720. According to some embodiments, the semiconductor package 70G further includes interconnection nodes 714 between and electrically connecting the plurality of second dies 720. According to some embodiments, the aggregate number of memory cells of the semiconductor package 70G using the multiple-die stacking scheme shown in FIG. 70G can exceed about eight billion. With the arrangement of multiple-die stacking scheme, the density of the memory cells can be greatly increased.

FIG. 7H is a schematic diagram of a semiconductor package 70H, in accordance with various embodiments of the present disclosure. The semiconductor package 70H is similar to the semiconductor packages 70B and 70G in many features, and thus descriptions of these similar features are not repeated for brevity. The semiconductor package 70G can be seen as a combination of the semiconductor packages 70B and 70G, in which the semiconductor package 70G includes the first die 70 and the plurality of second dies 720, e.g., second dies 720A, 720B and 720C stacking over one another. The first die 710 and the second dies 720 are bonded through the interconnection nodes 704 and 706 disposed on the bonding surfaces of the first die 710 or the second dies 720.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages as those of the embodiments introduced herein. Those skilled in the art should also realize that such equivalent constructions do not depart from the spirit and scope of the present disclosure, and that they may make various changes, substitutions, and alterations to the embodiments disclosed herein without departing from the spirit and scope of the present disclosure.

What is claimed is:

1. A dynamic random-access memory (DRAM)-based one time programming (OTP) memory device, comprising:
at least one memory bank comprising a plurality of memory array tiles (MATs) arranged in a matrix, wherein each of the plurality of MATs comprises:
a plurality of word lines extending along a row direction;
a plurality of bit lines extending along a column direction; and
a plurality of memory cells located on corresponding cross points of the plurality of word lines and the plurality of bit lines, each of the plurality of memory cells comprising a capacitor node,
wherein the capacitor nodes of the plurality of memory cells along the column direction in the memory bank are divided into a plurality of capacitor node segments, wherein at least two of the plurality of capacitor node segments are separately controllable.

2. The DRAM-based OTP memory device according to claim 1, wherein one of the plurality of capacitor node segments includes the capacitor nodes of the plurality of memory cells along one of the plurality of word lines.

3. The DRAM-based OTP memory device according to claim 1, wherein one of the plurality of capacitor node segments includes the capacitor nodes of the plurality of memory cells in one row of the plurality of MATs arranged along the row direction.

4. The DRAM-based OTP memory device according to claim 1, wherein one of the plurality of capacitor node segments includes the capacitor nodes of the plurality of memory cells in two rows of the plurality of MATs arranged along the row direction.

5. The DRAM-based OTP memory device according to claim 3, wherein the each of the plurality of capacitor node segments further comprises a plurality of sub-node segments arranged along the row direction, wherein at least two of the sub-node segments are separately controllable.

6. The DRAM-based OTP memory device according to claim 1, further comprising:
a controller;
a row decoder configured to receive a row address signal from the controller; and
a cell plate voltage (V_{PLT}) switch configured to receive a row select signal from the row decoder and control the at least two of the plurality of capacitor node segments.

7. The DRAM-based OTP memory device according to claim 6, further comprising a charge pump circuit configured to provide an OTP programming voltage to the V_{PLT} switch, wherein the V_{PLT}switch is configured to receive the OTP programming voltage from the charge pump circuit and transmit the OTP programming voltage to the plurality of capacitor node segments.

8. The DRAM-based OTP memory device according to claim 6, further comprising an external power pin configured to receive a OTP programming voltage from a power source to provide the OTP programming voltage to the V_{PLT} switch, wherein the V_{PLT} switch is configured to receive the OTP programming voltage from the power source and transmit the OTP programming voltage to the plurality of capacitor node segments.

9. The DRAM-based OTP memory device according to claim 5, further comprising:
a controller;
a row decoder configured to receive a row address signal from the controller;
a column decoder configured to receive a column address signal from the controller; and
a V_{PLT} switch configured to receive a row select signal from the row decoder and a column select signal from the column decoder and control the at least two of the plurality of capacitor node segments.

10. The DRAM-based OTP memory device according to claim 7, wherein the charge pump circuit is configured to receive an enable signal from the controller.

11. The DRAM-based OTP memory device according to claim 1, further comprising:
a sensing circuit configured to sense the plurality of memory cells to provide an initial logic state; and
a comparator configured to receive the initial logic state with a reference signal to provide a final logic state to the controller.

12. The DRAM-based OTP memory device according to claim 1, wherein the DRAM-based OTP memory device shares a similar structure with a DRAM memory.

13. The DRAM-based OTP memory device according to claim 1, wherein a number of the plurality of memory cells exceeds 8 billion.

14. A semiconductor package, comprising:
a substrate;
a DRAM memory device formed in the substrate; and
a DRAM-based OTP memory device formed in the substrate and comprising:
at least one memory bank comprising a plurality of memory array tiles (MATs) arranged in a matrix, wherein each of the plurality of MATs comprises:
a plurality of word lines extending along a row direction;
a plurality of bit lines extending along a column direction; and
a plurality of memory cells located on corresponding cross points of the plurality of word lines and the plurality of bit lines, each of the plurality of memory cells comprising a capacitor node,
wherein the capacitor nodes of the plurality of memory cells along the column direction in the memory bank are divided into a plurality of capacitor node segments, wherein at least two of the plurality of capacitor node segments are separately controllable.

15. The semiconductor package according to claim 14, wherein the plurality of memory cells of the DRAM-based OTP memory device and a plurality of memory cells of the DRAM memory device share a similar structure.

16. The semiconductor package according to claim 14, wherein the capacitor nodes of the DRAM-based OTP memory device and a plurality of capacitor nodes of the DRAM memory device are separately controllable.

17. A semiconductor package, comprising:
a logic device formed in a first substrate; and
a DRAM-based OTP memory device formed in a second substrate and stacking on the logic device, the DRAM-based OTP memory device comprising:
at least one memory bank comprising a plurality of memory array tiles (MATs) arranged in a matrix, wherein each of the plurality of MATs comprises:
a plurality of word lines extending along a row direction;
a plurality of bit lines extending along a column direction; and
a plurality of memory cells located on corresponding cross points of the plurality of word lines and the plurality of bit lines, each of the plurality of memory cells comprising a capacitor node,
wherein the capacitor nodes of the plurality of memory cells along the column direction in the memory bank are divided into a plurality of capacitor node segments, wherein at least two of the plurality of capacitor node segments are separately controllable.

18. The semiconductor package according to claim 17, further comprising a plurality of interconnection nodes formed between the logic device and the DRAM-based OTP memory device, wherein a number of the plurality of interconnection nodes exceeds 10,000.

19. The semiconductor package according to claim 18, wherein the plurality of interconnection nodes are formed by micro-bumping, nano-bumping or hybrid bonding.

20. The semiconductor package according to claim 17, further comprising a DRAM device formed in the second substrate and stacking on the logic device, wherein the plurality of memory cells of the DRAM-based OTP memory device and a plurality of memory cells of a DRAM memory device share a similar structure.
